(19) United States
(12) Patent Application Publication
(10) Pub. No.: US 2017/0162693 A1
(43) Pub. Date: Jun. 8, 2017

(54) APPARATUS AND METHODS TO CREATE MICROELECTRONIC DEVICE ISOLATION BY CATALYTIC OXIDE FORMATION

(71) Applicant: INTEL CORPORATION, Santa Clara, CA (US)

(72) Inventors: Gopinath Bhimarasetti, Portland, OR (US); Walid Hafez, Portland, OR (US); Joodong Park, Portland, OR (US); Weimin Han, Portland, OR (US); Raymond Cotner, Wilsonville, OR (US)

(73) Assignee: INTEL CORPORATION, Santa Clara, CA (US)

(21) Appl. No.: 15/323,726

(22) PCT Filed: Aug. 5, 2014
(86) PCT No.: PCT/US2014/049674

§ 371 Date: Jan. 3, 2017

(51) Int. Cl. H01L 29/78; H01L 21/762; H01L 29/66; H01L 29/423

(52) U.S. Cl. CPC H01L 29/7846; H01L 29/42376; H01L 21/76202; H01L 29/785; H01L 29/66795

(57) ABSTRACT

Non-planar transistor devices which include oxide isolation structures formed in semiconductor bodies thereof through the formation of an oxidizing catalyst layer on the semiconductor bodies followed by an oxidation process. In one embodiment, the semiconductor bodies may be formed from silicon-containing materials and the oxidizing catalyst layer may comprise aluminum oxide, wherein oxidizing the semiconductor body to form an oxide isolation zone forms a semiconductor body first portion and a semiconductor body second portion with the isolation zone substantially electrically separating the semiconductor body first portion and the semiconductor body second portion.

### TECHNICAL FIELD

Embodiments of the present description generally relate to the field of microelectronic devices, and, more particularly, to forming isolation structures between non-planar microelectronic transistors.

### BACKGROUND

Higher performance, lower cost, increased miniaturization of integrated circuit components, and greater packaging density of integrated circuits are ongoing goals of the microelectronic industry for the fabrication of microelectronic devices. To achieve these goals, transistors within the microelectronic devices must scale down, i.e. become smaller. Thus, the microelectronic industry has developed unique structures, such as non-planar transistors, including tri-gate transistors, FinFETs, omega-FETs, and double-gate transistors. The development of these non-planar transistor structures has, in turn, spawned the drive to improve their efficiency with improvements in their designs and/or in their fabrication processes.

### BRIEF DESCRIPTION OF THE DRAWINGS

The subject matter of the present disclosure is particularly pointed out and distinctly claimed in the concluding portion of the specification. The foregoing and other features of the present disclosure will become more fully apparent from the following description and appended claims, taken in conjunction with the accompanying drawings. It is understood that the accompanying drawings depict only several embodiments in accordance with the present disclosure and are, therefore, not to be considered limiting of its scope. The disclosure will be described with additional specificity and detail through use of the accompanying drawings, such that the advantages of the present disclosure can be more readily ascertained, in which:

FIG. 1 is an oblique view of a non-planar transistor, as known in the art.

FIG. 2 is an oblique view of a non-planar transistor having an isolation gap, as known in the art.

FIG. 3 is an oblique view of a non-planar transistor having an isolation zone formed by selective catalytic oxidation, according to an embodiment of the present description.

FIGS. 4-7 are oblique and side cross-sectional views of forming an isolation zone in a semiconductor body, according to an embodiment of the present description.

FIG. 8 is a flow chart of a process of fabricating an isolation zone in a semiconductor body, according to an embodiment of the present description.

FIG. 9 illustrates a computing device in accordance with one implementation of the present description.

### DESCRIPTION OF EMBODIMENTS

In the following detailed description, reference is made to the accompanying drawings that show, by way of illustration, specific embodiments in which the claimed subject matter may be practiced. These embodiments are described in sufficient detail to enable those skilled in the art to practice the subject matter. It is to be understood that the various embodiments, although different, are not necessarily mutually exclusive. For example, a particular feature, structure, or characteristic described herein, in connection with one embodiment, may be implemented within other embodiments without departing from the spirit and scope of the claimed subject matter. References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, it is to be understood that the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled. In the drawings, like numerals refer to the same or similar elements or functionality throughout the several views, and that elements depicted therein are not necessarily to scale with one another, rather individual elements may be enlarged or reduced in order to more easily comprehend the elements in the context of the present description.

The terms “over”, “to”, “between” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

Embodiments of the present description relate to the fabrication of non-planar transistor devices. In at least one embodiment, the present subject matter relates to forming oxide isolation structures in semiconductor bodies of non-planar transistors by the formation of a catalyst on the semiconductor bodies followed by an oxidation process.

In the fabrication of non-planar transistors, such as tri-gate transistors, FinFETs, omega-FETs, and double-gate transistors, non-planar semiconductor bodies may be used to form transistors capable of full depletion with very small gate lengths (e.g., less than about 30 nm). For example in a tri-gate transistor, the semiconductor bodies generally have a fin-shape with a top surface and two opposing sidewalls formed on a bulk semiconductor substrate or a silicon-on-insulator substrate. A gate dielectric may be formed on the top surface and sidewalls of the semiconductor body and a gate electrode may be formed over the gate dielectric on the top surface of the semiconductor body and adjacent to the gate dielectric on the sidewalls of the semiconductor body. Thus, since the gate dielectric and the gate electrode are adjacent to three surfaces of the semiconductor body, three separate channels and gates are formed. As there are three separate channels formed, the semiconductor body can be fully depleted when the transistor is turned on.

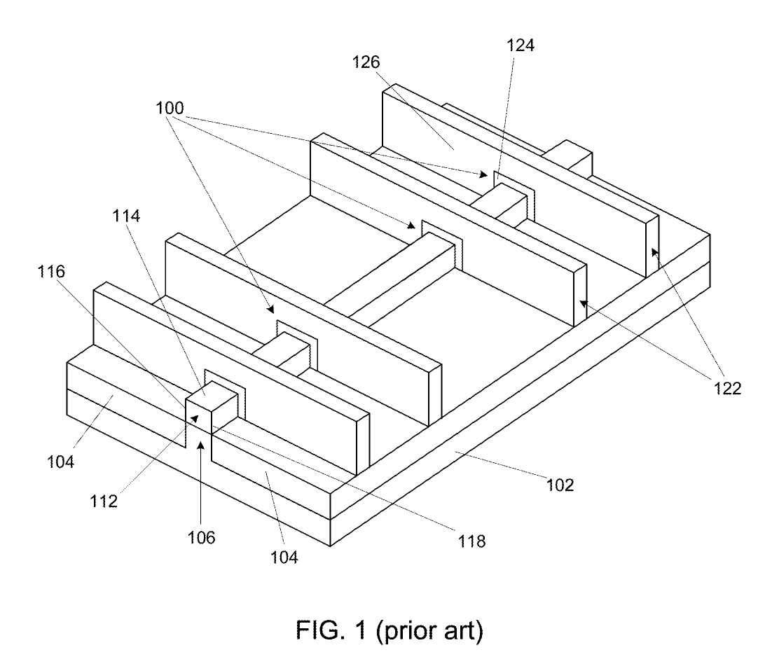

FIG. 1 is a perspective view of a number of transistors including a number gates formed on a semiconductor body, which is formed on a substrate. In an embodiment of the present disclosure, the substrate 102 may be a silicon-containing material, such as monocrystalline silicon, having a pair of spaced apart isolation regions 104, such as shallow trench isolation (STI) regions, which define the substrate active region 106 therebetween. The substrate 102, however, need not necessarily be a silicon monocrystalline substrate and can be other types of substrates, such as a germanium, a gallium arsenide, indium antimonide, lead telluride, indium arsenide, indium phosphide, gallium arsenide, gallium antimonide, and the like, any of which may be combined with silicon. The isolations regions 104 maybe be formed by forming trenches in the substrate 102 filling the trenches with an electrically insulative material, such as silicon oxide (SiO₂).

Each transistor 100, shown as tri-gate transistors, includes a semiconductor body 112 formed adjacent the substrate active region 106. The semiconductor body 112 may be a fin-shaped structure having a top surface 114 and a pair of laterally opposite sidewalls, sidewall 116 and opposing sidewall 118. The semiconductor body 112 may be a silicon-containing material, such as monocrystalline or single crystalline silicon. In one embodiment of the present disclosure, the semiconductor body 112 may be formed from the same semiconductor material as the substrate 102. In another embodiment of the present disclosure, the semiconductor body 112 may be formed from a semiconductor material different than the material used to form the substrate 102. In still another embodiment of the present disclosure, the semiconductor body 112 may be formed from a single crystalline semiconductor having a different lattice constant or size than the bulk semiconductor substrate 102, so that the semiconductor body 112 will have a strain induced therein.

As further shown in FIG. 1, at least one gate 122 may be form over the semiconductor body 112. A gate 122 may be fabricated by forming a gate dielectric layer 124 on or adjacent to the top surface 114 and on or adjacent to the pair of laterally opposing sidewalls 116, 118 of the semiconductor body 112, and forming a gate electrode 126 on or adjacent the gate dielectric layer 124.

The gate dielectric layer 124 may be formed from any well-known gate dielectric material, including but not limited to silicon dioxide (SiO₂), silicon oxynitride (SiOₓN_{y}), silicon nitride (Si₃N₄), and high-k dielectric materials such as hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. The gate dielectric layer 124 can be formed by well-known techniques, such as by depositing a gate electrode material, such as chemical vapor deposition (“CVD”), physical vapor deposition (“PVD”), atomic layer deposition (“ALD”), and then patterning the gate electrode material with well-known photolithography and etching techniques, as will be understood to those skilled in the art.

As shown in FIG. 1, the gate electrode 126 may be formed on or adjacent to the gate dielectric layer 124. The gate electrode 126 can be formed of any suitable gate electrode material. In an embodiment of the present disclosure, the gate electrode 126 may be formed from materials that include, but are not limited to, polysilicon, tungsten, ruthenium, palladium, platinum, cobalt, nickel, hafnium, zirconium, titanium, tantalum, aluminum, titanium carbide, zirconium carbide, tantalum carbide, hafnium carbide, aluminum carbide, other metal carbides, metal nitrides, and metal oxides. The gate electrode 126 can be formed by well-known techniques, such as by blanket depositing a gate electrode material and then patterning the gate electrode material with well-known photolithography and etching techniques, as will be understood to those skilled in the art.

The “width” of transistor is equal to the height (not shown) of semiconductor body 112 at the sidewall 116, plus the width (not shown) of semiconductor body of 112 at the top surface 114, plus the height (not shown) of semiconductor body 112 at the opposing sidewall 118. In an implementation of the present disclosure, the semiconductor body 112 runs in a direction substantially perpendicular to the gates 122.

It is understood that a source region and a drain region (not shown) may be formed in the semiconductor body 112 on opposite sides of the gate electrode 126. The source and drain regions may be formed of the same conductivity type, such as N-type or P-type conductivity. The source and drain regions may have a uniform doping concentration or may include sub-regions of different concentrations or doping profiles such as tip regions (e.g., source/drain extensions). In some implementations of an embodiment of the present disclosure, the source and drain regions may have the substantially the same doping concentration and profile while in other implementations they may vary.

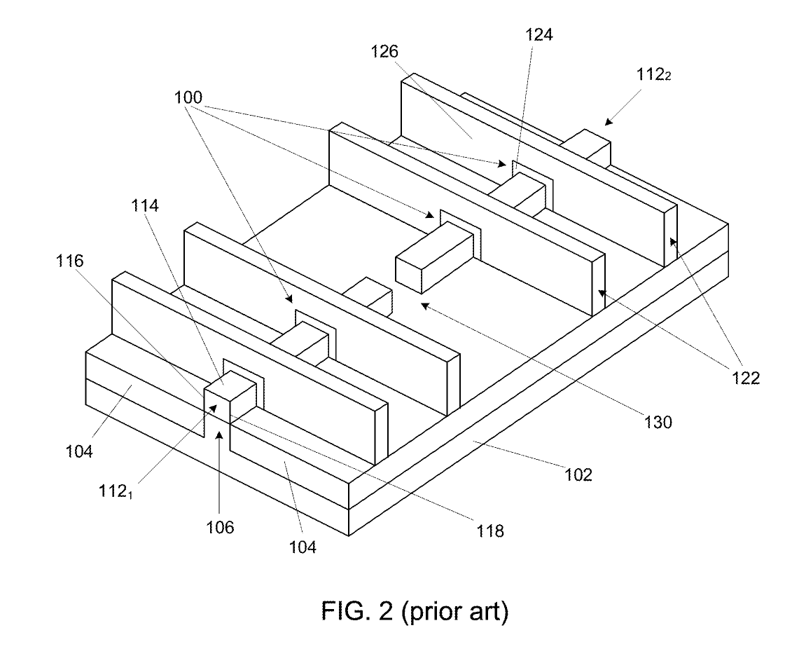

In the fabrication of the transistors 100, as shown in FIG. 2, relatively long semiconductor body 112 and/or bodies may be formed, then portions thereof may be removed to form a gap 130 either before or after the formation of the gates 122. The formation of the gap 130 or gaps forms a desired length for the semiconductor body by electrically isolating one portion 112₁ of the semiconductor body from another portion 112₂. The desired length is determined by the numbers of gates 122 to be formed along a particular portion of the semiconductor body 112. However, the processes for forming the gaps 130, such as dry etching, have issues, including, but not limited to, significant variability, etch bias, and incomplete etching at the base of the fin, as will be understood to those skilled in the art. The etch bias may result in the gap 130 having a width which is larger than a desired critical dimension, and incomplete etching may result in insufficient electrical isolation, as will be understood to those skilled in the art. Furthermore, in transistors devices where a strained semiconductor body 112 is advantageous, the gap 130 forms a free surface edge can result in a relaxation of the strain on the semiconductor body 112 proximate the gap 130. This relaxation extends, as a decreasing function, along the length of the semiconductor body away from the gap 130, which results in varying performance from transistor to the next.

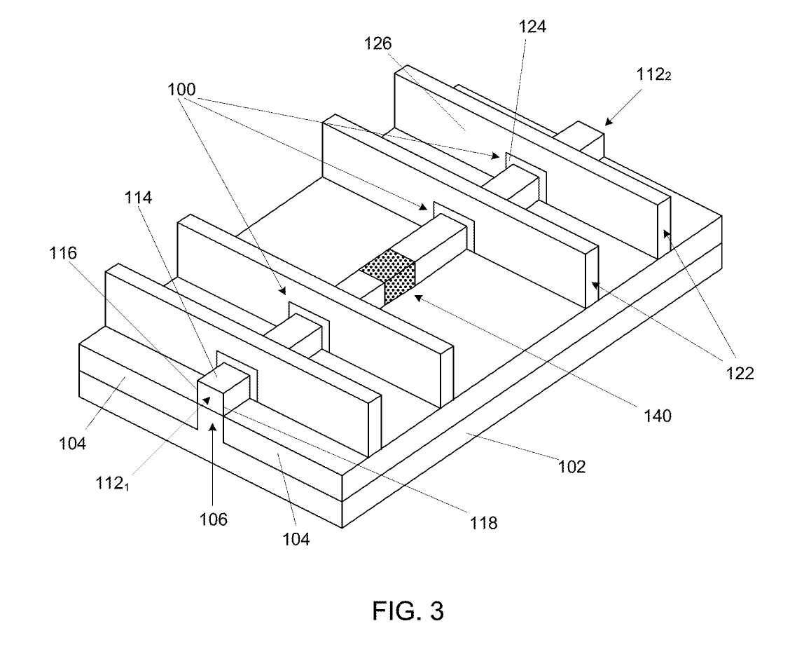

As shown in FIG. 3, in an embodiment of the present disclosure, an oxide isolation zone 140 may be formed in the semiconductor body 112 which results in the formation of the semiconductor body first portion 112₁ and the semiconductor body second portion 112₂, which are substantially electrically isolated from one another by the oxide isolation zone 140. The oxide isolation zone 140 may be formed by selectively converting a portion of the semiconductor body 112 to a dielectric oxide.

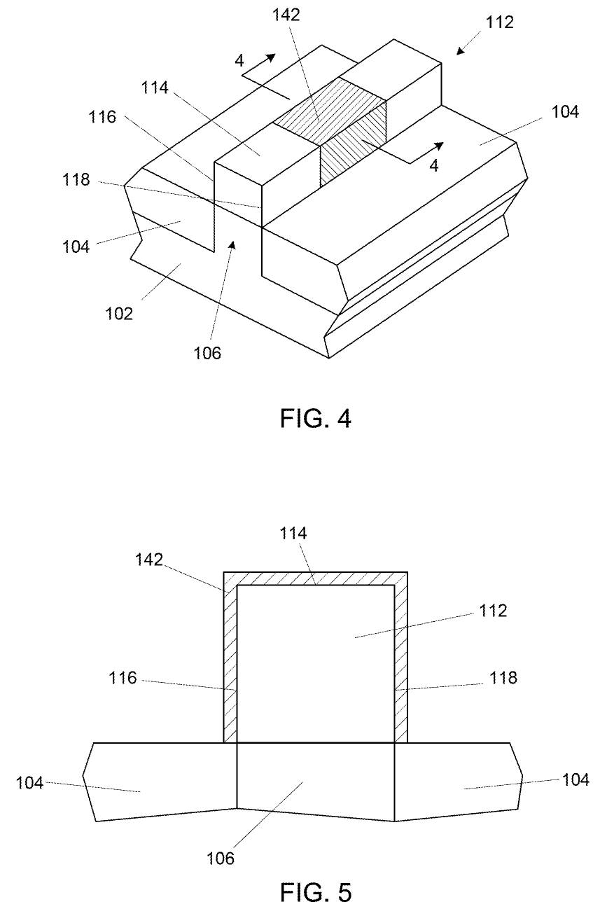

In one embodiment, as shown in FIGS. 4 and 5, an oxidizing catalyst layer 142 may be patterned on the semiconductor body 112. As shown in FIG. 5, the oxidizing catalyst layer 142 may be conformally deposited on the semiconductor body top surface 114 and the semiconductor body sidewalls 116 and 118 by any technique known in the art. The oxidizing catalyst layer 142 may be any appropriate material capable of acting as a catalyst for the oxidation of the underlying semiconductor body 112. In one embodiment, the oxidizing catalyst layer 142 may be aluminum, aluminum oxide, tantalum oxide, yttrium oxide, hafnium oxide, titanium oxide, zirconium oxide, similar metals or their associated oxides. In a specific embodiment, the semiconductor body 112 may be a silicon-containing material and the oxidizing catalyst layer 142 may be aluminum oxide. In one embodiment, the oxidizing catalyst layer 142 may be deposited by an atomic layer deposition process, which may serve to minimize thickness variations of the oxidizing catalyst layer 142. The oxidizing catalyst layer 142 may be patterned on the semiconductor body 112 by any technique known in the art, including, but not limited to, photolithographic and etching techniques.

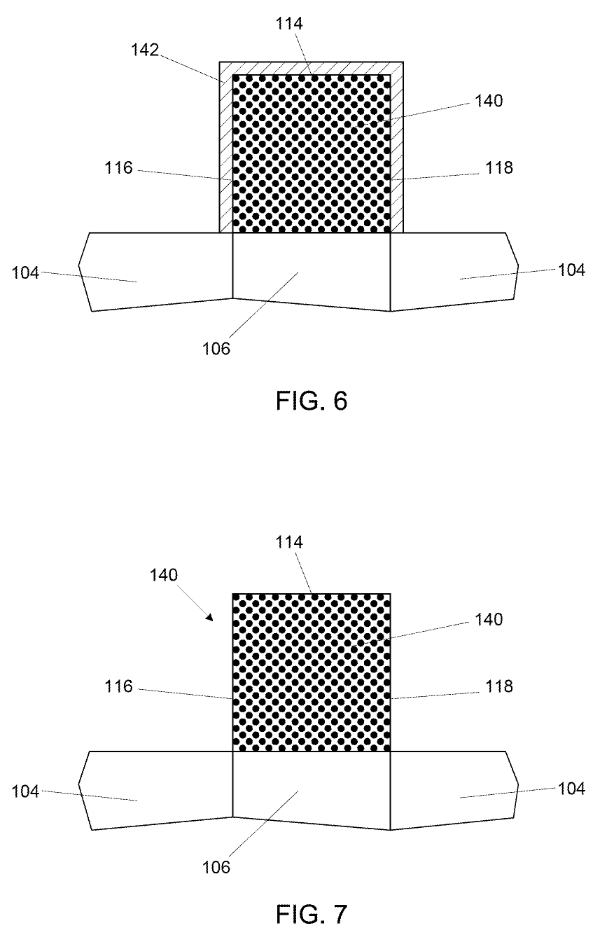

As shown in FIG. 6, the semiconductor body 112 (see FIG. 5) may be subjected to an oxidation process to convert the semiconductor body 112 (see FIG. 5) beneath or adjacent the oxidizing catalyst layer 142 into the oxide isolation zone 140. In one embodiment, the oxidation process may be performed typical oxidation techniques such as atmospheric oxidation, such as dry oxidation, wet oxidation, rapid thermal anneal, and the like, or sub-atmospheric techniques, such as plasma oxidation and the like. The presence of the oxidizing catalyst layer 142 may result in the semiconductor body 112 converting to an oxide at a rate of about ten (10) times faster than portions of the semiconductor body 112 not in contact with the oxidizing catalyst layer 142. This may result in a deeper oxidation defined by the area covered by the oxidizing catalyst layer 142. Further, as the deep oxidation only occurs at the contact area of the oxidizing catalyst layer 142, the desired critical dimension of the oxide isolation zone 140 may be maintained.

In a specific embodiment, the oxidizing catalyst layer 142 may be aluminum oxide deposited by atomic layer deposition on a portion of the semiconductor body 112 comprising silicon. The semiconductor body 112 and oxidizing catalyst layer 142 may be exposed to a low pressure, gaseous mixture of hydrogen gas and/or oxygen gas for a pre-determined time duration (determined by the thickness of oxide required), and at a temperature of between about 400° C. to 650° C. (more specifically, about 630° C.).

As shown in FIG. 7, after the formation of the oxide isolation zone 140, the oxidizing catalyst layer 142 (see FIG. 6) may be optionally removed. It is understood that the oxide isolation zone(s) 140 may be formed prior to or after the formation of the gates 122 (see FIG. 3). It is further understood that although a single semiconductor body 112 is illustrated for the sake of clarity, there may be a plurality of semiconductor bodies 112 extending substantially parallel to one another on the substrate 102 (see FIG. 1).

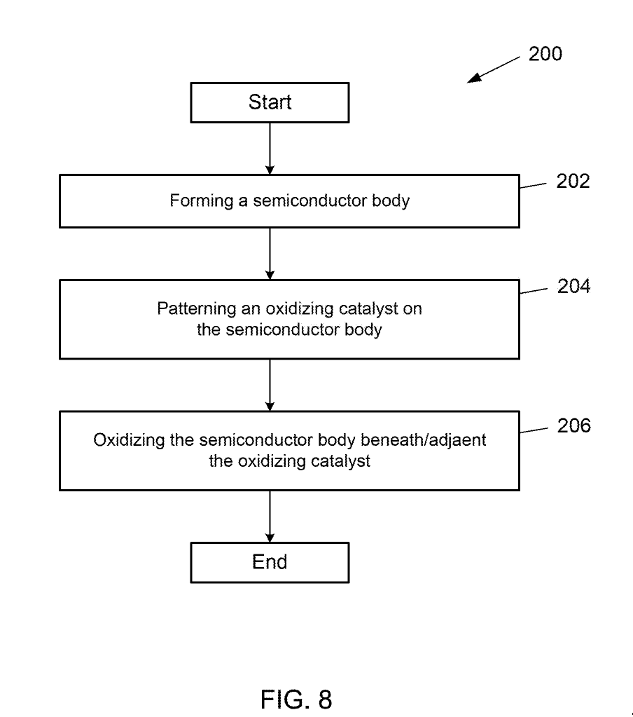

FIG. 8 is a flow chart of a process 200 of fabricating a non-planar transistor according to an embodiment of the present description. As set forth in block 202, a semiconductor body may be formed. An oxidizing catalyst may be patterned on the semiconductor body, as set forth in block 204. As set forth in block 206, the semiconductor body may be oxidized to form an oxide isolation zone within the semiconductor body beneath or adjacent the oxidizing catalyst.

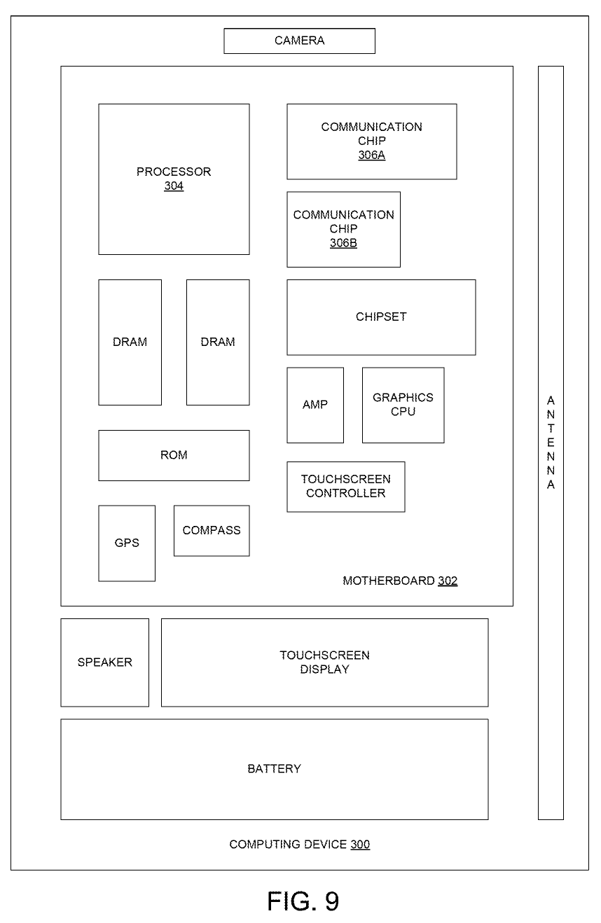

FIG. 9 illustrates a computing device 300 in accordance with one implementation of the present description. The computing device 300 houses a board 302. The board 302 may include a number of components, including but not limited to a processor 304 and at least one communication chip 306A, 306B. The processor 304 is physically and electrically coupled to the board 302. In some implementations the at least one communication chip 306A, 306B is also physically and electrically coupled to the board 302. In further implementations, the communication chip 306A, 306B is part of the processor 304.

Depending on its applications, the computing device 300 may include other components that may or may not be physically and electrically coupled to the board 302. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 306A, 306B enables wireless communications for the transfer of data to and from the computing device 300. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 306 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 300 may include a plurality of communication chips 306A, 306B. For instance, a first communication chip 306A may be dedicated to shorter range wireless communications such as Wi-Fi and Bluetooth and a second communication chip 306B may be dedicated to longer range wireless communications such as GPS, EDGE, GPRS, CDMA, WiMAX, LTE, Ev-DO, and others.

The processor 304 of the computing device 300 may include non-planar transistors fabricated in the manner described above. The term “processor” may refer to any device or portion of a device that processes electronic data from registers and/or memory to transform that electronic data into other electronic data that may be stored in registers and/or memory. Furthermore, the communication chip 306A, 306B may include non-planar transistors fabricated in the manner described above.

In various implementations, the computing device 300 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 300 may be any other electronic device that processes data.

It is understood that the subject matter of the present description is not necessarily limited to specific applications illustrated in FIGS. 1-9. The subject matter may be applied to other microelectronic device and assembly applications, as well as any appropriate transistor application, as will be understood to those skilled in the art.

The following examples pertain to further embodiments, wherein Example 1 is a method of forming a non-planar transistor, comprising forming a semiconductor body, patterning an oxidizing catalyst layer on the semiconductor body, and oxidizing the semiconductor body to form an oxide isolation zone within the semiconductor body adjacent the oxidizing catalyst.

In Example 2, the subject matter of Example 1 can optionally include including removing the oxidizing catalyst after oxidizing the semiconductor body.

In Example 3, the subject matter of any of Examples 1 to 2 can optionally include forming the semiconductor body comprising forming a fin-shaped structure.

In Example 4, the subject matter of any of Examples 1 to 3 can optionally include forming the semiconductor body comprising forming a silicon-containing semiconductor body.

In Example 5, the subject matter of any of Examples 1 to 4 can optionally include patterning an oxidizing catalyst layer on the semiconductor body comprising patterning a material selected from the group consisting of aluminum, aluminum oxide, tantalum oxide, yttrium oxide, hafnium oxide, titanium oxide, and zirconium oxide.

In Example 6, the subject matter of any of Examples 1 to 5 can optionally include forming the semiconductor body comprising forming a silicon semiconductor body, and wherein patterning the oxidizing catalyst layer on the semiconductor body comprising patterning aluminum oxide on the silicon semiconductor body.

In Example 7, the subject matter of any of Examples 1 to 6 can optionally include oxidizing the semiconductor body comprising exposing semiconductor body to a gaseous mixture including at least one of hydrogen, oxygen, nitrous oxide, and steam at a temperature of between about 400° C. to 650° C., and at a below atmospheric pressure.

In Example 8, the subject matter of any of Examples 1 to 7 can optionally include forming at least one transistor gate on the semiconductor body.

In Example 9, the subject matter of any of Examples 1 to 8 can optionally include oxidizing the semiconductor body to form an oxide isolation zone and form a semiconductor body first portion and a semiconductor body second portion from the semiconductor body with the isolation zone substantially electrically separating the semiconductor body first portion and the semiconductor body second portion.

In Example 10, the subject matter of any of Examples 1 to 9 can optionally include forming at least one transistor gate on at least one of the semiconductor body first portion and the semiconductor body second portion.

The following examples pertain to further embodiments, wherein Example 11 is a non-planar transistor comprising a semiconductor body including a first portion and a second portion, and an oxide isolation zone comprising an oxidized portion of the semiconductor body, wherein the oxide isolation zone substantially electrically isolates the semiconductor body first portion and the semiconductor body second portion.

In Example 12, the subject matter of Example 11 can optionally include the semiconductor body comprising a silicon-containing material.

In Example 13, the subject matter of any of Examples 11 to 12 can optionally include the oxide isolation zone comprising silicon dioxide.

In Example 14, the subject matter of any of Examples 11 to 13 can optionally include an oxidizing catalyst layer patterned adjacent the oxide isolation zone.

In Example 15, the subject matter of any of Examples 11 to 14 can optionally include the oxidizing catalyst layer comprising a material selected from the group consisting of aluminum, aluminum oxide, tantalum oxide, yttrium oxide, hafnium oxide, titanium oxide, and zirconium oxide.

In Example 16, the subject matter of any of Examples 11 to 15 can optionally include at least one transistor gate on at least one of the semiconductor body first portion and the semiconductor body second portion.

The following examples pertain to further embodiments, wherein Example 17 is an electronic system, comprising a board, and a microelectronic device attached to the board, wherein the microelectronic device includes non-planar transistor comprising a semiconductor body including a first portion and a second portion, and an oxide isolation zone comprising an oxidized portion of the semiconductor body, wherein the oxide isolation zone substantially electrically isolates the semiconductor body first portion and the semiconductor body second portion.

In Example 18, the subject matter of Example 17 can optionally include the semiconductor body comprising a silicon-containing material.

In Example 19, the subject matter of any of Examples 17 to 18 can optionally include the oxide isolation zone comprising silicon dioxide.

In Example 20, the subject matter of any of Examples 17 to 19 can optionally include an oxidizing catalyst layer patterned adjacent the oxide isolation zone.

In Example 21, the subject matter of any of Examples 17 to 20 can optionally include the oxidizing catalyst layer comprising a material selected from the group consisting of aluminum, aluminum oxide, tantalum oxide, yttrium oxide, hafnium oxide, titanium oxide, and zirconium oxide.

In Example 22, the subject matter of any of Examples 17 to 21 can optionally include at least one transistor gate on at least one of the semiconductor body first portion and the semiconductor body second portion.

Having thus described in detail embodiments of the present description, it is understood that the present description defined by the appended claims is not to be limited by particular details set forth in the above description, as many apparent variations thereof are possible without departing from the spirit or scope thereof.

1. A method of forming a non-planar transistor, comprising:
forming a semiconductor body;
patterning an oxidizing catalyst layer on the semiconductor body; and
oxidizing the semiconductor body to form an oxide isolation zone within the semiconductor body adjacent the oxidizing catalyst.

2. The method of claim 1, further including removing the oxidizing catalyst after oxidizing the semiconductor body.

3. The method of claim 1, wherein forming the semiconductor body comprises forming a fin-shaped structure.

4. The method of claim 1, wherein forming the semiconductor body comprises forming a silicon-containing semiconductor body.

5. The method of claim 1, wherein patterning an oxidizing catalyst layer on the semiconductor body comprises patterning a material selected from the group consisting of aluminum, aluminum oxide, tantalum oxide, yttrium oxide, hafnium oxide, titanium oxide, and zirconium oxide.

6. The method of claim 1, wherein forming the semiconductor body comprises forming a silicon semiconductor body, and wherein patterning the oxidizing catalyst layer on the semiconductor body comprises patterning aluminum oxide on the silicon semiconductor body.

7. The method of claim 6, wherein oxidizing the semiconductor body comprising exposing semiconductor body to a gaseous mixture of at least one of hydrogen, oxygen, nitrous oxide, and steam at a temperature of between about 400° C. to 650° C. and at a pressure below atmospheric pressure.

8. The method of claim 1, further comprising forming at least one transistor gate on the semiconductor body.

9. The method of claim 1, wherein oxidizing the semiconductor body to form an oxide isolation zone forms a semiconductor body first portion and a semiconductor body second portion with the isolation zone substantially electrically separating the semiconductor body first portion and the semiconductor body second portion.

10. The method of claim 9, further comprising forming at least one transistor gate on at least one of the semiconductor body first portion and the semiconductor body second portion.

11. A non-planar transistor, comprising:
a semiconductor body including a first portion and a second portion; and
an oxide isolation zone comprising an oxidized portion of the semiconductor body, wherein the oxide isolation zone substantially electrically isolates the semiconductor body first portion and the semiconductor body second portion.

12. The non-planar transistor of claim 11, wherein the semiconductor body comprises a silicon-containing material.

13. The non-planar transistor of claim 12, wherein the oxide isolation zone comprises silicon dioxide.

14. The non-planar transistor of claim 11, further comprising an oxidizing catalyst layer patterned adjacent the oxide isolation zone.

15. The non-planar transistor of any of claims 14, wherein the oxidizing catalyst layer comprises a material selected from the group consisting of aluminum, aluminum oxide, tantalum oxide, yttrium oxide, hafnium oxide, titanium oxide, and zirconium oxide.

16. The non-planar transistor of claim 11, further comprising at least one transistor gate on at least one of the semiconductor body first portion and the semiconductor body second portion.

17. An electronic system, comprising:
a board; and
a microelectronic device attached to the board, wherein the microelectronic device includes at least one non-planar transistor comprising a semiconductor body including a first portion and a second portion, and an oxide isolation zone comprising an oxidized portion of the semiconductor body, wherein the oxide isolation zone substantially electrically isolates the semiconductor body first portion and the semiconductor body second portion.

18. The electronic system of claim 17, wherein the semiconductor body comprises a silicon-containing material.

19. The electronic system of claim 18, wherein the oxide isolation zone comprises a silicon dioxide.

20. The electronic system of claim 17, further comprising an oxidizing catalyst layer patterned adjacent the oxide isolation zone.

21. The electronic system of claim 20, wherein the oxidizing catalyst layer comprises a material selected from the group consisting of aluminum, aluminum oxide, tantalum oxide, yttrium oxide, hafnium oxide, titanium oxide, and zirconium oxide.

22. The electronic system of claim 17, further comprising at least one transistor gate on at least one of the semiconductor body first portion and the semiconductor body second portion.
